(19) United States
(12) Patent Application Publication
(10) Pub. No.: US 2013/0244343 A1
(43) Pub. Date: Sep. 19, 2013

(54) METHOD FOR PREPARING A THIN FILM DEVICE AND METHOD FOR PREPARING A COMMON MODE FILTER USING THE SAME

(71) Applicants: HUAI LUH CHANG, MIAOLI COUNTY (TW); YU CHIA CHANG, TAICHUNG CITY (TW); MING FUNG HSIEH, CHANGHUA COUNTY (TW); HSIU MEI HSU, MIAOLI COUNTY (TW); KUO JUNG FU, TAIPEI CITY (TW)

(72) Inventors: HUAI LUH CHANG, MIAOLI COUNTY (TW); YU CHIA CHANG, TAICHUNG CITY (TW); MING FUNG HSIEH, CHANGHUA COUNTY (TW); HSIU MEI HSU, MIAOLI COUNTY (TW); KUO JUNG FU, TAIPEI CITY (TW)

(73) Assignee: INPAQ TECHNOLOGY CO., LTD., MIAOLI (TW)

(21) Appl. No.: 13/424,036

(22) Filed: Mar. 19, 2012

(51) Int. Cl. H01L 43/12

(52) U.S. Cl. 438/3; 257/E43.006

(57) ABSTRACT

One aspect of the present invention provides a method for preparing a thin film device with an insulation layer from a dry polyimide film and a method for preparing a common mode filter using the same. A method for preparing a thin film device according to this aspect of the present invention includes the steps of forming at least one first conductive pattern on a substrate; placing a dry polyimide film on the first conductive pattern; applying a force to the dry polyimide film such that the dry polyimide film fills spaces in the first conductive pattern; and forming at least one second conductive pattern on the dry polyimide film.

### BACKGROUND OF THE INVENTION

1. Technical Field

The present invention relates to a method for preparing a thin film device and a method for preparing a common mode filter using the same, and more particularly, relates to a method for preparing an insulation layer from a dry polyimide film and a method for preparing a common mode filter using the same.

2. Background

In a thin film device, an insulation layer such as polyimide film is widely used to electrically separate the conductive pattern of different layers. In the prior art, the polyimide film is generally formed by spin coating technique, and it is generally desired to make the polyimide film uniform in thickness.

FIGS. 1 and 2 illustrate a method for preparing a thin film device 10 according to the prior art. Referring to FIG. 1, deposition, lithography, electroplating and etching processes are performed to form a first conductive pattern 13 on a substrate 11, and a first insulation layer 15 is then formed on the first conductive pattern 13 by spin coating process and thermal treating process.

Referring to FIG. 2, deposition, lithography, electroplating and etching processes are performed to form a second conductive pattern 17 on the first insulation layer 15, and a second insulation layer 19 is then formed on the second conductive pattern 17 by the spin coating process and thermal treating process.

The first insulation layer 15 formed by the spin coating process can electrically separate the first conductive pattern 13 from the second conductive pattern 17. However, the surface of the first insulation layer 15 formed by the spin coating process is not planar, which may impede alignment of the lithography process for preparing the second conductive pattern 17, i.e., influencing the position of the subsequently formed second conductive pattern 17. In addition, the thickness of the first insulation layer 15 between the first conductive pattern 13 and the second conductive pattern 17 is not uniform, which influences the electrical properties of the thin film device 10.

### SUMMARY

One aspect of the present invention provides a method for preparing a thin film device with an insulation layer formed from a dry polyimide film and a method for preparing a common mode filter using the same.

A method for preparing a thin film device according to this aspect of the present invention comprises the steps of forming a first conductive pattern on a substrate; placing a dry polyimide film on the first conductive pattern; applying a force to the dry polyimide film such that the dry polyimide film fills spaces in the first conductive pattern; and forming a second conductive pattern on the dry polyimide film

A method for preparing a common mode filter according to another aspect of the present invention comprises the steps of forming a first conductive pattern on a substrate; placing a dry polyimide film on the first conductive pattern; applying a force to the dry polyimide film such that the dry polyimide film fills spaces in the first conductive pattern; and forming second conductive pattern on the dry polyimide film

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 and FIG. 2 illustrate a method for preparing a thin film device according to the prior art;

FIG. 3 to FIG. 8 illustrate a method for preparing a thin film device according to one embodiment of the present invention;

FIG. 9 to FIG. 18 illustrate a method for preparing a common mode filter in accordance with an embodiment of the present invention; and

FIG. 19 to FIG. 27 illustrate a method for preparing a common mode filter in accordance with an embodiment of the present invention.

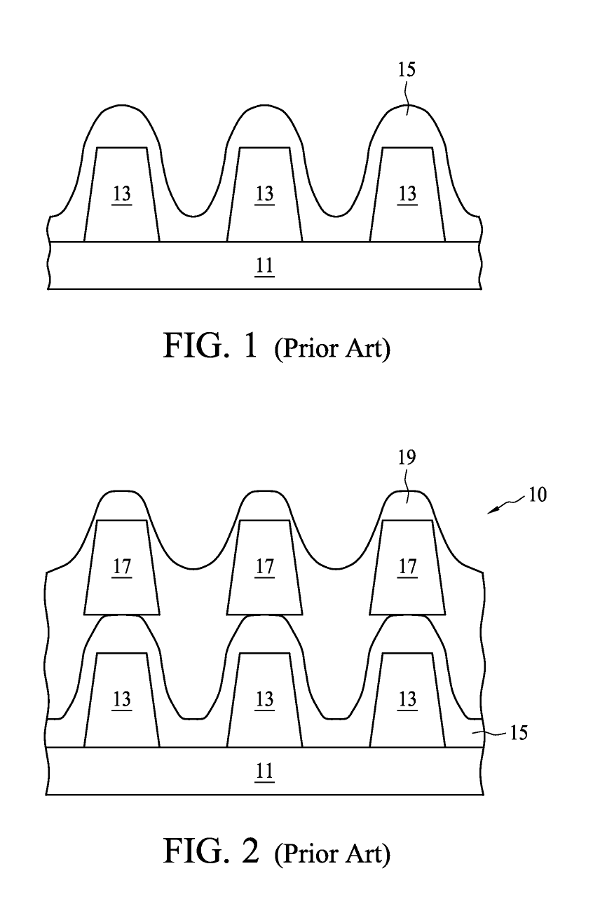

### DETAILED DESCRIPTION OF THE INVENTION

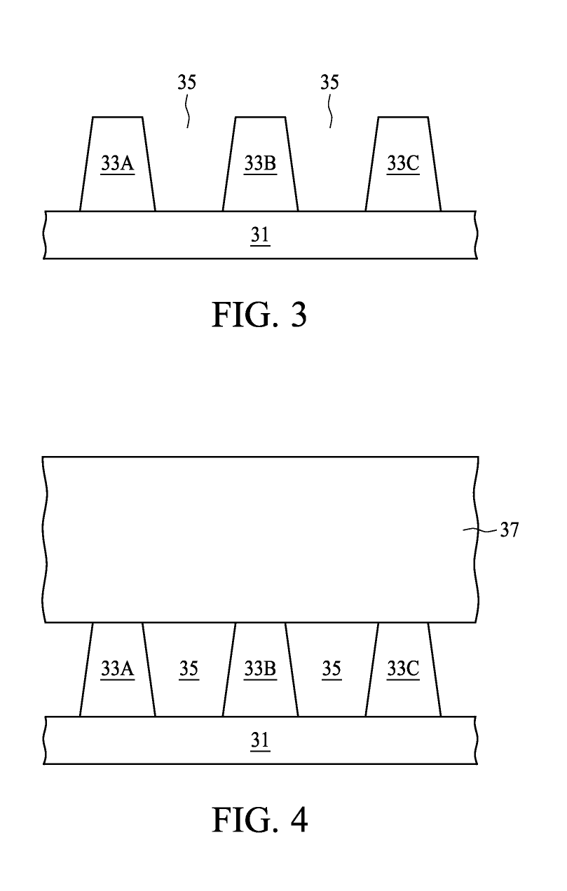

FIGS. 3 to 8 illustrate a method for preparing a thin film device 30 according to one embodiment of the present invention. Referring to FIG. 3, deposition, lithography, electroplating and etching processes are performed to form a first conductive pattern 33A-33C with spaces 35 on a substrate 31. Subsequently, a dry polyimide film 37 is placed on the first conductive pattern 33A-33C, as shown in FIG. 4.

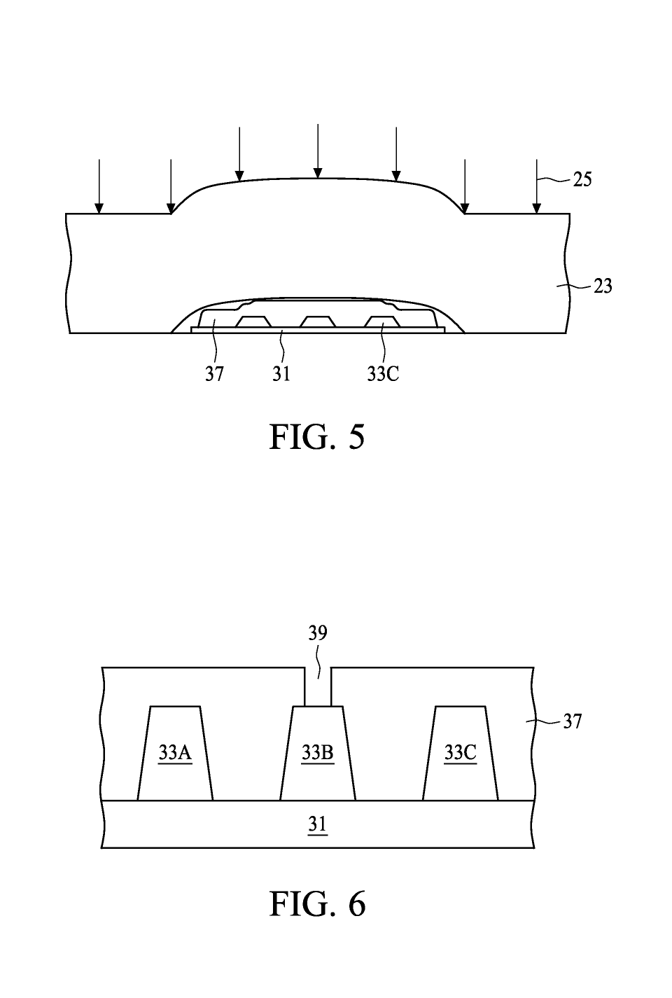

Referring to FIG. 5, a force 25 is applied to the dry polyimide film 37 such that the dry polyimide film 37 fills the spaces 35 in the first conductive pattern 33A-33C. Subsequently, a curing process is performed on the dry polyimide film 37 serving as an insulation layer to electrically isolate the first conductive pattern 33A-33C.

In one embodiment of the present invention, the force 25 is applied to the dry polyimide film 37 by a roller or by a hydraulic press through an elastomer 23 such as rubber or diaphragm. In one embodiment of the present invention, the force 25 is applied to the dry polyimide film 37 substantially in a vacuum environment. In one embodiment of the present invention, the force 25 is applied to the dry polyimide film 37 substantially at a temperature between 50° C. and 110° C., which is not lower than the glass transition temperature of the dry polyimide film 37. In one embodiment of the present invention, the curing process is a thermal treating process performed at a temperature between 160° C. and 370° C.

Referring to FIG. 6, a patterning process is performed on the dry polyimide film 37 to form a hole 39 exposing a portion of the first conductive pattern 33B. In one embodiment of the present invention, the patterning process includes lithography process.

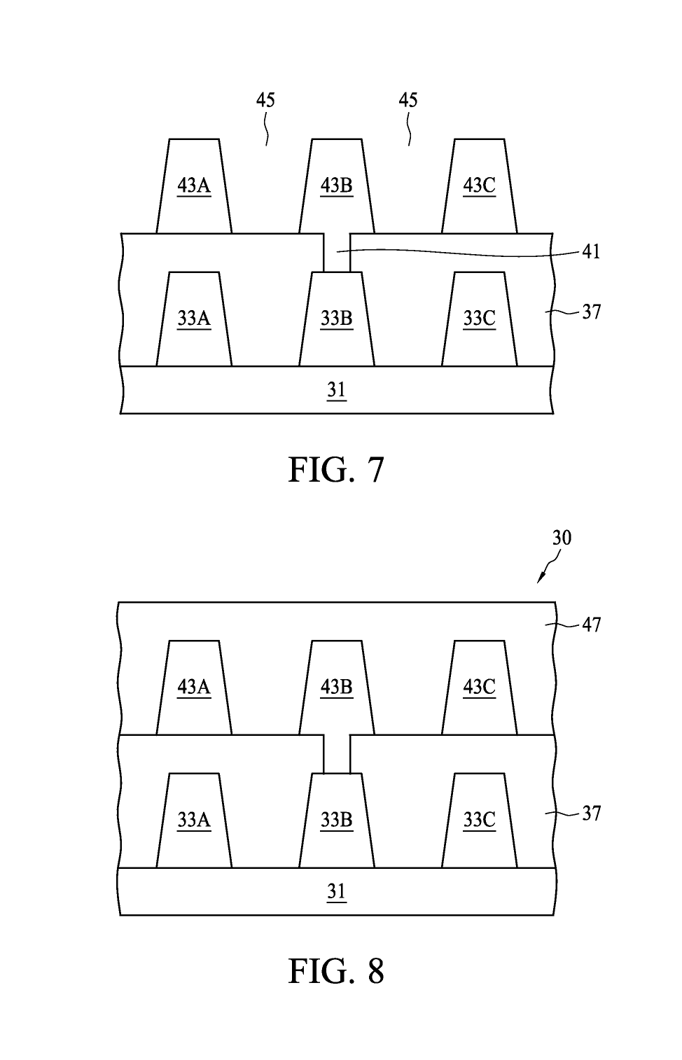

Referring to FIG. 7, fabrication processes including deposition, lithography, electroplating and etching processes are performed on the dry polyimide film 37 to form a second conductive pattern 43A-43C with spaces 45 on the dry polyimide film 37. In addition, the fabrication processes also form a via 41 connecting the second conductive pattern 43B and the first conductive pattern 33B, as shown in FIG. 7. Subsequently, the fabrication processes shown in FIG. 4 and FIG. 5 are performed to form a dry polyimide film 47 serving as an insulation layer to electrically isolate the second conductive pattern 43A-43C of the thin film device 30, as shown in FIG. 8.

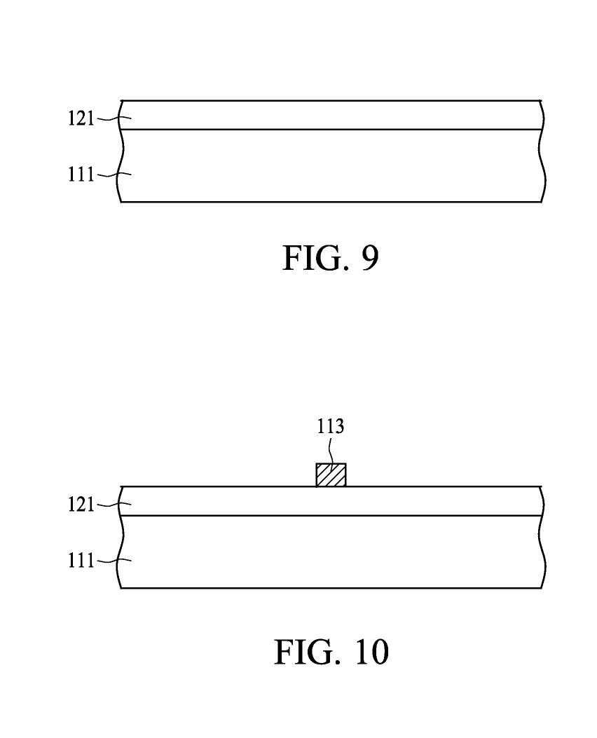

FIGS. 9 to 18 illustrate a method for preparing a common mode filter 100 in accordance with an embodiment of the present invention.

Referring to FIG. 9, a first insulation layer 121 such as the polyimide film is formed on a magnetic substrate 111 by spin coating process.

Referring to FIG. 10, a lower coil leading layer 113 is formed on the first insulation layer 121 by a thin-film metal deposition process, a photolithography process, an electroplating process and an etching process. In one embodiment of the present invention, the thin-film metal deposition process is a sputtering process.

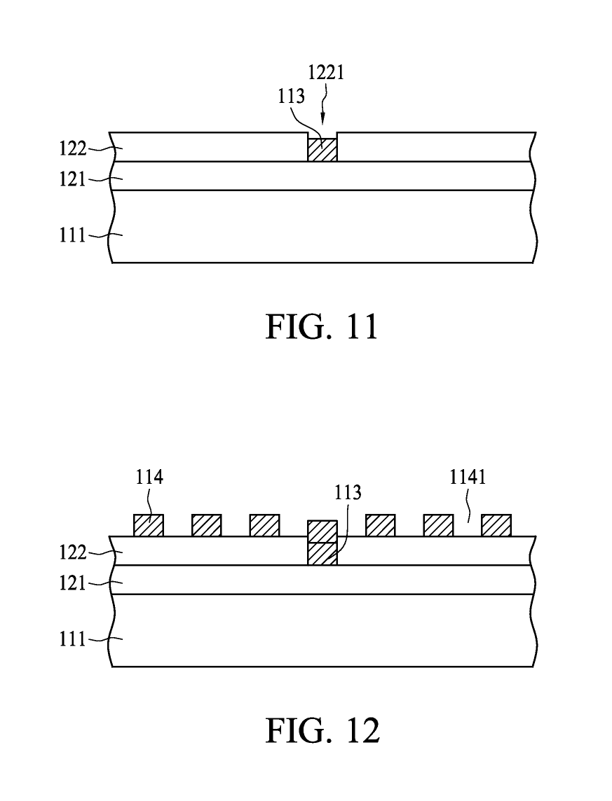

Referring to FIG. 11, a second insulation layer 122 is formed from a dry polyimide film on the lower coil leading layer 113 by the fabrication process described in FIG. 4 and FIG. 5, i.e., placing a dry polyimide film on the lower coil leading layer 113 and applying a force to the dry polyimide film such that the dry polyimide film covers the lower coil leading layer 113. Subsequently, a patterning process is performed on the second insulation layer 122 to form a hole 1221 by the fabrication process described in FIG. 6, wherein the hole 1221 exposes a portion of the lower coil leading layer 113.

Referring to FIG. 12, a first coil main body layer 114 is formed on the second insulation layer 122 by a thin-film metal deposition process, a photolithography process, an electroplating process and an etching process. In one embodiment of the present invention, the thin-film metal deposition process is a sputtering process. In one embodiment of the present invention, the first coil main body layer 114 includes a conductive pattern with spaces 1141.

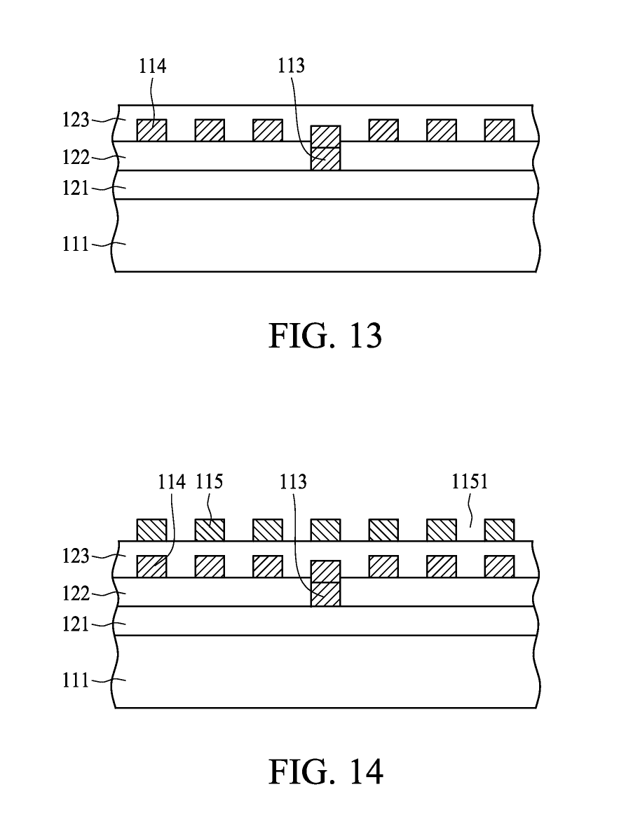

Referring to FIG. 13, a third insulation layer 123 is formed from a dry polyimide film on the first coil main body layer 114 by the fabrication process described in FIG. 4 and FIG. 5, i.e., placing a dry polyimide film on the first coil main body layer 114 and applying a force to the dry polyimide film such that the dry polyimide film fills the spaces 1141 in the conductive pattern of the first coil main body layer 114.

Referring to FIG. 14, a second coil main body layer 115 is formed on the third insulation layer 123 by a thin-film metal deposition process, a photolithography process, an electroplating process and an etching process. In one embodiment of the present invention, the thin-film metal deposition process is a sputtering process. In one embodiment of the present invention, the second coil main body layer 115 includes a conductive pattern with spaces 1151.

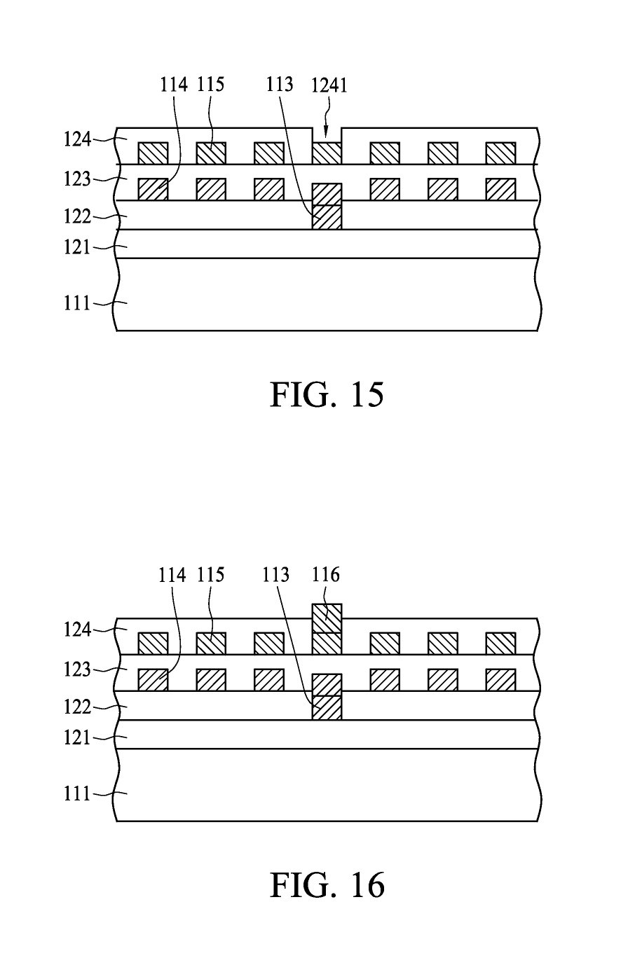

Referring to FIG. 15, a fourth insulation layer 124 is formed from a dry polyimide film on the second coil main body layer 115 by the fabrication process described in FIG. 4 and FIG. 5, i.e., placing a dry polyimide film on the second coil main body layer 115 and applying a force to the dry polyimide film such that the dry polyimide film fills the spaces 1151 in the conductive pattern of the second coil main body layer 115. Subsequently, a patterning process is performed on the fourth insulation layer 124 to form a hole 1241 by the fabrication process described in FIG. 6, wherein the hole 1241 exposes a portion of the second coil main body layer 115.

Referring to FIG. 16, an upper coil leading layer 116 is formed by a thin-film metal deposition process, a photolithography process, an electroplating process and an etching process. In one embodiment of the present invention, the thin-film metal deposition process is a sputtering process.

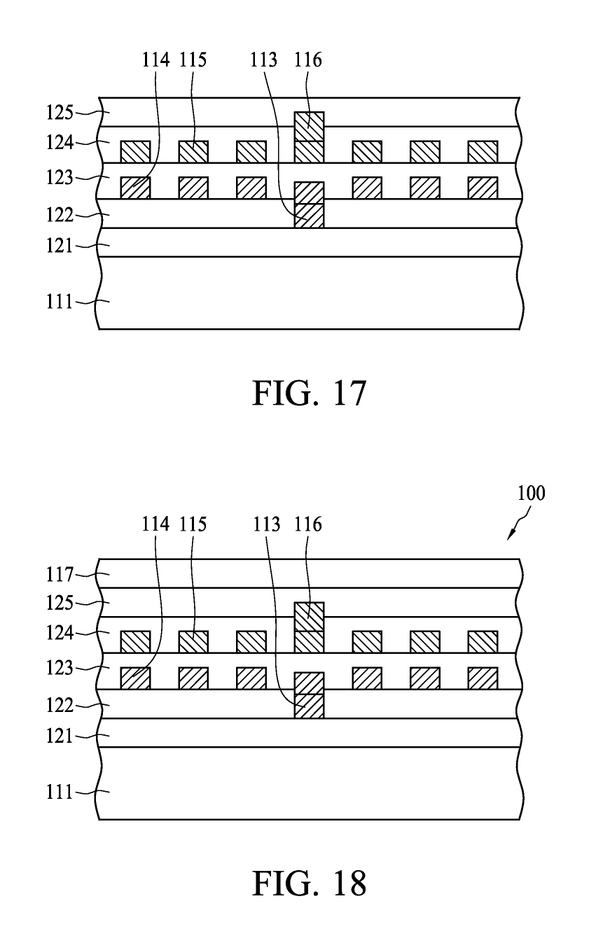

Referring to FIG. 17, a fifth insulation layer 125 is formed from a dry polyimide film on the upper coil leading layer 116 by the fabrication process described in FIG. 4 and FIG. 5, i.e., placing a dry polyimide film on the upper coil leading layer 116 and applying a force to the dry polyimide film such that the dry polyimide film covers the upper coil leading layer 116.

Referring to FIG. 18, a magnetic material layer 117 is formed on the fifth insulation layer 125 by a screen printing process to complete the common mode filter 100.

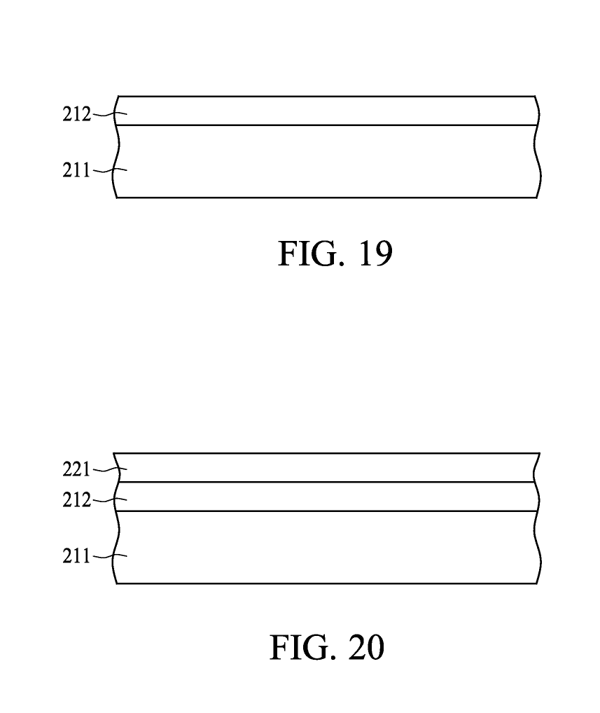

FIGS. 19 to 27 illustrate a method for preparing a common mode filter 200 in accordance with an embodiment of the present invention.

Referring to FIG. 19, a magnetic material layer 212 is formed on a non-magnetic dielectric substrate 211. In one embodiment of the present invention, the non-magnetic dielectric substrate 211 may includes Al₂O₃, AlN, glass, or quartz. In one embodiment of the present invention, the magnetic material layer 212 has high permeability and may includes ferrites such as NiZn ferrite material or MnZn ferrite material.

Referring to FIG. 20, a first insulation layer 221 such as the polyimide film is formed on the magnetic material layer 212 by spin coating process.

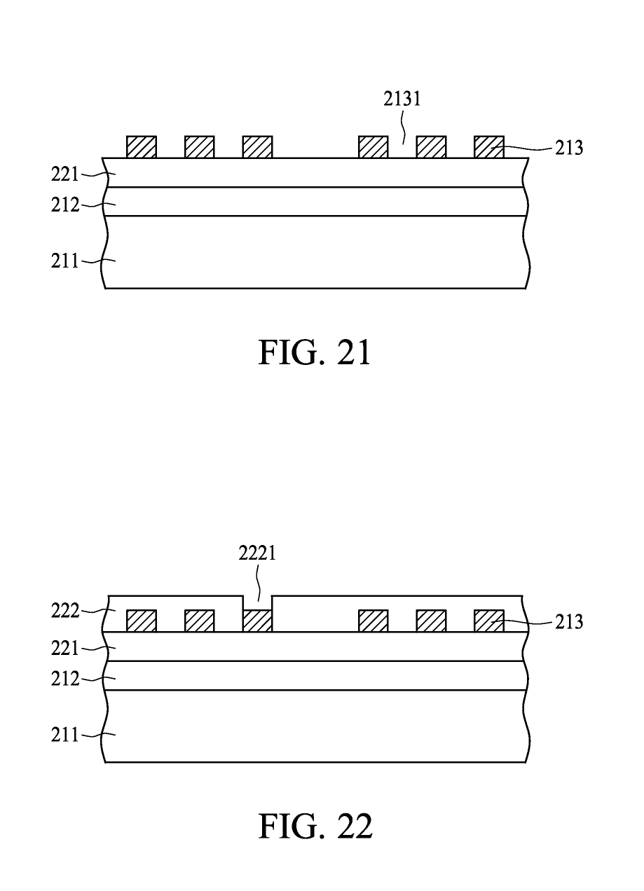

Referring to FIG. 21, a first coil main body layer 213 is formed on the first insulation layer 221 by a thin-film metal deposition process, a photolithography process, an electroplating process and an etching process. In one embodiment of the present invention, the thin-film metal deposition process is a sputtering process. In one embodiment of the present invention, the first coil main body layer 213 includes a conductive pattern with spaces 2131.

Referring to FIG. 22, a second insulation layer 222 is formed from a dry polyimide film on the first coil main body layer 213 by the fabrication process described in FIG. 4 and FIG. 5, i.e., placing a dry polyimide film on the first coil main body layer 213 and applying a force to the dry polyimide film such that the dry polyimide film fills the spaces 2121 in the conductive pattern of the first coil main body layer 213. Subsequently, a patterning process is performed on the second insulation layer 222 to form a hole 2221 by the fabrication process described in FIG. 6, wherein the hole 2221 exposes a portion of the first coil main body layer 213.

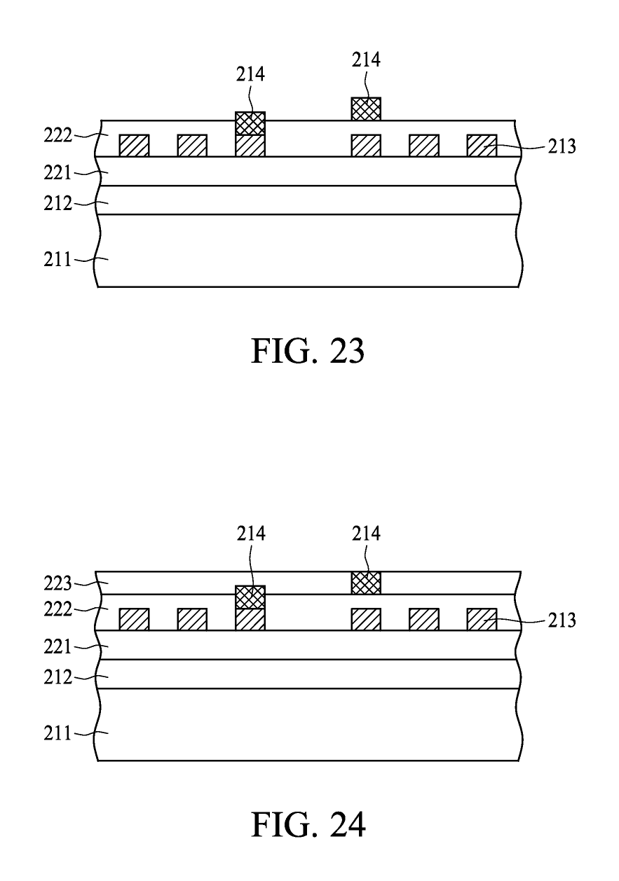

Referring to FIG. 23, a coil leading layer 214 is formed in the hole 2221 by a thin-film metal deposition process, a photolithography process, an electroplating process and an etching process. In one embodiment of the present invention, the thin-film metal deposition process is a sputtering process, and the coil leading layer 214 in the hole 2221 contacts the first coil main body layer 213.

Referring to FIG. 24, a third insulation layer 223 is formed from a dry polyimide film on the coil leading layer 214 by the fabrication process described in FIG. 4 and FIG. 5, i.e., placing a dry polyimide film on the coil leading layer 214 and applying a force to the dry polyimide, thereby isolating the coil leading layer 214.

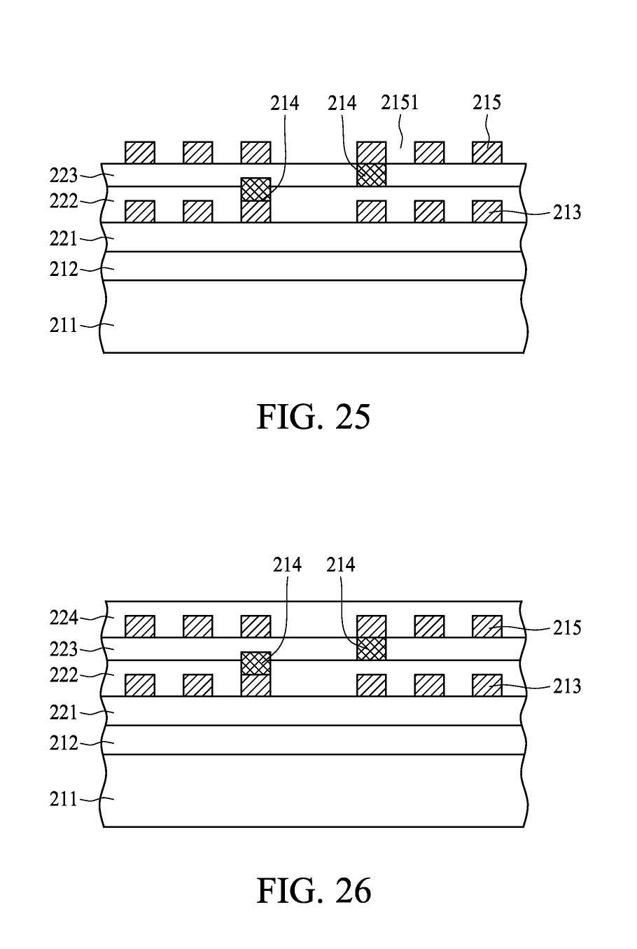

Referring to FIG. 25, a second coil main body layer 215 is formed on the third insulation layer 223 by a thin-film metal deposition process, a photolithography process, an electroplating process and an etching process. In one embodiment of the present invention, the thin-film metal deposition process is a sputtering process, and the second coil main body layer 215 contacts the coil leading layer 214 in the third insulation layer 223. In one embodiment of the present invention, the second coil main body layer 215 includes a conductive pattern with spaces 2151.

Referring to FIG. 26, a fourth insulation layer 224 is formed from a dry polyimide film on the second coil main body layer 215 by the fabrication process described in FIG. 4 and FIG. 5, i.e., placing a dry polyimide film on the second coil main body layer 215 and applying a force to the dry polyimide film such that the dry polyimide film fills the spaces 2151 in the conductive pattern of the second coil main body layer 215.

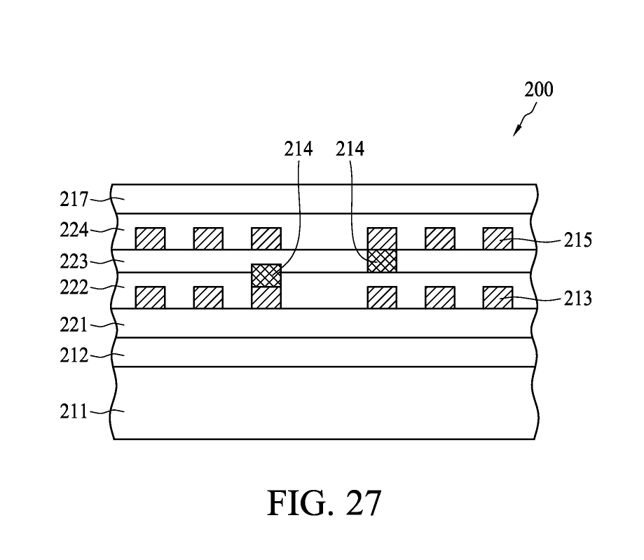

Referring to FIG. 27, a magnetic material layer 217 is formed on the fourth insulation layer 224 by a screen printing process to complete the common mode filter 200.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for preparing a thin film device, comprising the steps of:
forming at least one first conductive pattern on a substrate;
placing a dry polyimide film on the first conductive pattern;
applying a force to the dry polyimide film such that the dry polyimide film has a substantially planar top surface and fills spaces in the first conductive pattern, wherein the force is applied to the dry polyimide film by a hydraulic press; and
forming at least one second conductive pattern on the dry polyimide film.

2. The method for preparing a thin film device of claim 1, wherein the force is applied to the dry polyimide film by a roller.

3. (canceled)

4. The method for preparing a thin film device of claim 1, wherein the force is applied to the dry polyimide film through an elastomer.

5. The method for preparing a thin film device of claim 4, wherein the elastomer comprises rubber or diaphragm.

6. The method for preparing a thin film device of claim 1, wherein the force is applied to the dry polyimide film substantially in a vacuum environment.

7. The method for preparing a thin film device of claim 1, wherein the force is applied to the dry polyimide film at a temperature not lower than a glass transition temperature of the dry polyimide film.

8. The method for preparing a thin film device of claim 1, further comprising a step of patterning the dry polyimide film before the forming of the second conductive pattern.

9. The method for preparing a thin film device of claim 8, further comprising a step of curing the dry polyimide film before the forming of the second conductive pattern.

10. The method for preparing a thin film device of claim 9, wherein the curing of the dry polyimide film is performed by a thermal treating process at a temperature between 160° C. and 370° C.

11. A method for preparing a common mode filter, comprising the steps of:
forming at least one first conductive pattern on a substrate;
placing a dry polyimide film on the first conductive pattern;
applying a force to the dry polyimide film such that the dry polyimide film fills spaces in the first conductive pattern; and
forming at least one second conductive pattern on the dry polyimide film.

12. The method for preparing a common mode filter of claim 11, wherein the force is applied to the dry polyimide film by a roller.

13. The method for preparing a common mode filter of claim 11, wherein the force is applied to the dry polyimide film by a hydraulic press.

14. The method for preparing a common mode filter of claim 11, wherein the force is applied to the dry polyimide film through an elastomer.

15. The method for preparing a common mode filter of claim 14, wherein the elastomer comprises rubber or diaphragm.

16. The method for preparing a common mode filter of claim 11, wherein the force is applied to the dry polyimide film substantially in a vacuum environment.

17. The method for preparing a common mode filter of claim 11, wherein the force is applied to the dry polyimide film at a temperature not lower than a glass transition temperature of the dry polyimide film.

18. The method for preparing a common mode filter of claim 11, further comprising a step of patterning the dry polyimide film before the forming of the second conductive pattern.

19. The method for preparing a common mode filter of claim 18, further comprising a step of curing the dry polyimide film before the forming of the second conductive pattern.

20. The method for preparing a common mode filter of claim 19, wherein the curing of the dry polyimide film is performed by a thermal treating process at a temperature between 160° C. and 370° C.
